(19) United States
(12) Patent Application Publication
(10) Pub. No.: US 2006/0266548 A1
(43) Pub. Date: Nov. 30, 2006

(54) Flexible flat cable, printed circuit board, and electronic apparatus

(76) Inventors: Masaya Hirashima, Ome-shi (JP); Tokihiko Mori, Kunitachi-shi (JP)

Correspondence Address: KNOBBE MARTENS OLSON & BEAR LLP, 2040 MAIN STREET, FOURTEENTH FLOOR, IRVINE, CA, 92614, US

(21) Appl. No.: 11/441,898

(22) Filed: May 26, 2006

(30) Foreign Application Priority Data
May 30, 2005 (JP) 2005-157350

(51) Int. Cl. H05K 1/16; H05K 1/00; H01B 7/08

(52) U.S. Cl. 174/260; 174/268; 174/117 F

(57) ABSTRACT

According to one embodiment, a connecting portion of conductors has a first region containing copper as main component, and a second region provided on the first region and containing tin and copper as main components. At least part of a surface region of the second region is formed of a tin-copper alloy.

### CROSS-REFERENCE TO RELATED APPLICATIONS

This application is based upon and claims the benefit of priority from Japanese Patent Application No. 2005-157350, filed May 30, 2005, the entire contents of which are incorporated herein by reference.

### BACKGROUND

1. Field

One embodiment of the invention relates to a flexible flat cable, a printed circuit board including the flexible flat cable, and an electronic apparatus having an electronic component connected to the printed circuit board by the flexible flat cable.

2. Description of the Related Art

In conventional art, copper wires plated with metal such as tin and lead to decrease the contact resistance and improve the continuity have been used as a conductor used for flexible flat cables. In recent years, it is required not to use lead for various wires used for electronic apparatuses, from the environmental point of view. Therefore, it is considered applying copper wires plated with tin or tin alloy not containing lead.

However, as disclosed in, for Experimental embodiment, Jpn. Pat. Appln. KOKAI Pub. No. 2005-48205, if a flexible flat cable using copper wire plated with tin or tin alloy not containing lead is engaged with a connector, the metal molecules on the surface of the plating are pushed out and grown in a whisker form by stress applied on the engaging portion, that is, whisker is generated and short circuit is caused between conductors.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is a schematic diagram illustrating an Experimental embodiment of a flexible flat cable according to the present invention.

FIG. 2 is a cross-sectional view taken along line X-X′ of FIG. 1.

FIG. 3 is a schematic cross-sectional view for explaining a structure of a conductor layer of a connecting portion.

FIG. 4 is a schematic diagram of an Experimental embodiment of a printed circuit board according to the present invention.

FIG. 5 is a schematic diagram illustrating an Experimental embodiment of an electronic apparatus according to the present invention.

### DETAILED DESCRIPTION

Various embodiments according to the invention will be described hereinafter with reference to the accompanying drawings. In general, according to one embodiment of the invention, a flexible flat cable according to the present invention comprises a pair of insulating sheets having flexibility, and a plurality of conductors which are arranged at intervals in lines between the insulating sheets and have at their end portions a connecting portion exposed from the insulating sheets; wherein the conductors contain tin and copper as main components, the connecting portion has a first region containing copper as main component, and a second region which contains tin and copper as main components and is formed on the first region, and at least part of a surface region of the second region is formed of a tin-copper alloy.

Further, a printed circuit board according to the present invention comprises the above flexible flat cable, and comprises a substrate, a conductor pattern provided on the substrate, a connector which has a contact portion provided on the substrate in electrical connection with the conductor pattern and having a tin alloy coating layer, and a housing holding the contact portion and having a fitting port into which a connecting portion of a connecting part is fitted, and the flexible flat cable whose connecting portion is inserted into the fitting port as a connecting part to electrically connect the conductors and the contact portion.

Further, an electronic apparatus according to the present invention has a structure wherein the above printed circuit board is connected to electronic parts by the flexible flat cable.

The conductors containing tin and copper as main components used for the present invention substantially consist of tin and copper, and do not contain lead. They may contain a trace quantity of other elements which do not influence the characteristic of the conductors. Experimental embodiments of the state of the tin and copper in the conductors are a combination of a copper phase and a tin phase formed on the copper phase, a combination of a copper phase and a tin-copper alloy phase formed on the copper phase, and a combination of a copper phase and a tin phase and a tin-copper alloy phase which are formed on the copper phase.

Further, the first region used for the present invention, which contains copper as main component, corresponds to the copper phase, substantially consists of copper and does not contain lead. The first region may contain a trace quantity of other elements which do not influence the characteristic of the first region.

Further, the second region used for the present invention, which contains tin and copper as main components, substantially consists of tin and copper and does not contain lead. The second region may contain a trace quantity of other elements which do not influence the characteristic of the second region. Experimental embodiments of the second region are a combination of a copper phase and a tin-copper alloy phase formed on the copper phase, and a combination of a copper phase and a tin phase and a tin-copper alloy phase which are formed on the copper phase. Therefore, a tin-copper alloy phase exists in at least part of a surface region of the second region.

According to the present invention, a tin-copper alloy phase exists on at least part of a surface region of the connecting portion. This structure prevents occurrence of whisker in the surface region. This structure achieves a flexible flat cable using inexpensive conductors not containing lead, which does not cause short circuit between the conductors, and has a sufficiently low contact resistance with connectors.

Further, using the flexible flat cable achieves a highly reliable connection at low cost with a connector mounted on a printed circuit board, without causing short circuit between conductors.

Further, using the flexible flat cable achieves a highly reliable connection at low cost between a printed circuit board and electronic parts, without causing short circuit between conductors.

The present invention is explained in more detail with reference to the drawings.

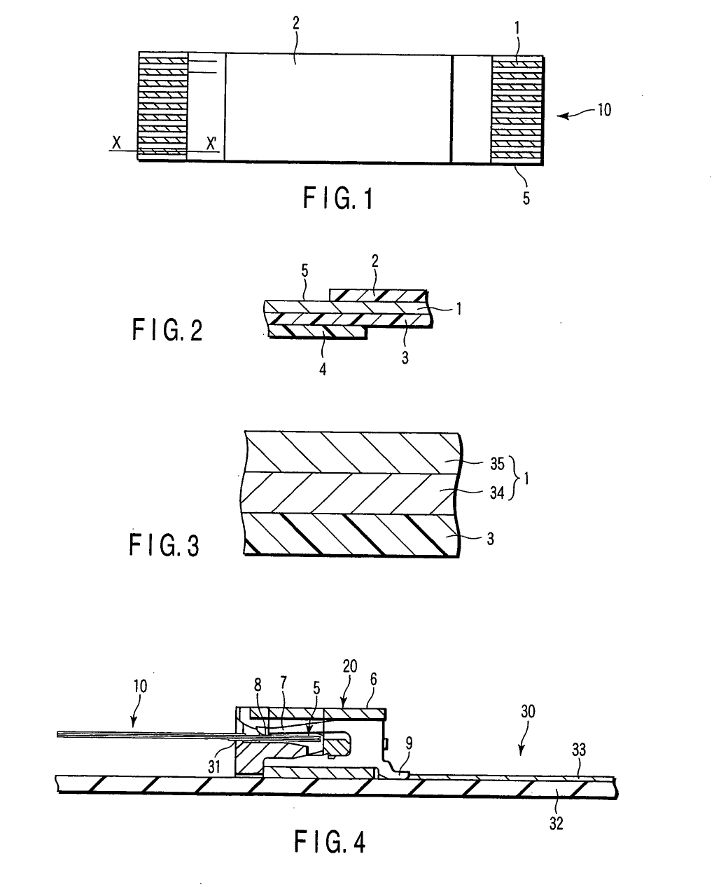

FIG. 1 is a front view of an Experimental embodiment of a flexible flat cable according to the present invention, and FIG. 2 is a cross-sectional view taken along line X-X′ of FIG. 1.

As shown in FIGS. 1 and 2, a flexible flat cable 10 comprises an insulating belt-like sheet 3 having flexibility and made of polyethylene terephthalate or the like, a plurality of conductors 1 which contains tin and copper as main components and are arranged in lines at intervals on the insulating belt-like sheet 3, and an insulating belt-like sheet 2 which is laminated on the insulating belt-like sheet 3 with the conductors 1 interposed therebetween, has flexibility and is formed of polyethylene terephthalate or the like. The insulating belt-like sheet 2 has a length shorter than that of the insulating belt-like sheet 3, and both ends of the insulating belt-like sheet 2 are arranged inside the both ends of the conductors 1. Thereby, the both ends of the conductors 1 are exposed and form connecting portions 5. Further, reinforcing plates 4 are provided on a surface of the insulating belt-like sheet 3 opposite to the respective connecting portions 5, to extend slight inward from the regions opposing the connecting portions 5. The reinforcing plates 4 are formed of polyethylene terephthalate or the like, and protect the connecting portions 5 to maintain the strength of the connection portions 5.

FIG. 3 illustrates a schematic cross-sectional view for explaining a structure of conductor layer in the connecting portions.

As shown in FIG. 3, the exposed conductor layer 1 of the connecting portions 5 has a copper phase 34 formed on the insulating belt-like sheet 3, and a tin-copper alloy phase 35 formed on the copper phase 34. Therefore, the surface region of the conductor layer 1 is formed of tin-copper alloy.

The exposed conductor layer 1 of the connecting portions 5 is obtained by arranging copper wires in lines at intervals on the insulating belt-like sheet 3, then plating the copper wires with a tin layer, and annealing at least the connecting portions at 220 to 300° C. Thereby, the tin-copper alloy phase is formed on the copper phase, such that at least part of the tin-copper alloy phase reaches the surface region. In the model diagram of FIG. 3, only the tin-copper alloy phase is formed on the copper phase. However, in the present invention, the tin phase and the tin-copper alloy phase may exist together on the copper phase, as long as at least part of the tin-copper alloy phase reaches the surface region.

FIG. 4 is a schematic diagram of an Experimental embodiment of a printed circuit board according to the present invention.

A printed circuit board 30 comprises an insulating substrate 32, a conductor pattern 33 provided on the insulating substrate 32, a connector 20 that is electrically connected to the conductor pattern 33, and a flexible flat cable 10 inserted in and connected to the connector 20. The connector 20 and the conductor pattern 33 can be electrically connected by soldering a terminal 9 of the connector 20 to a terminal (not shown) connected to the conductor pattern 33.

The connector 20 has a contact portion 7 having a tin alloy coating layer, and a housing 6 holding the contact portion 7 and having a fitting port 31 into which a connecting portion of connecting parts are fitted.

Experimental embodiments of the tin alloy used for the contact portion are tin-silver alloy, tin-copper alloy such as Sn-Su₂ alloy, tin-bismuth alloy, and tin-lead alloy.

In the printed circuit board 30, a flexible flat cable 10 having the same structure as illustrated in FIGS. 1 and 2 is used as connecting parts of the connector 20. The connecting portion 5 of the flexible flat cable 10 is inserted into the fitting port 31, and the conductors 1 and the contact portion 7 are brought into contact in a contact position 8. Thereby, a connecting structure of the flexible flat cable 10 and the connector 20 is formed.

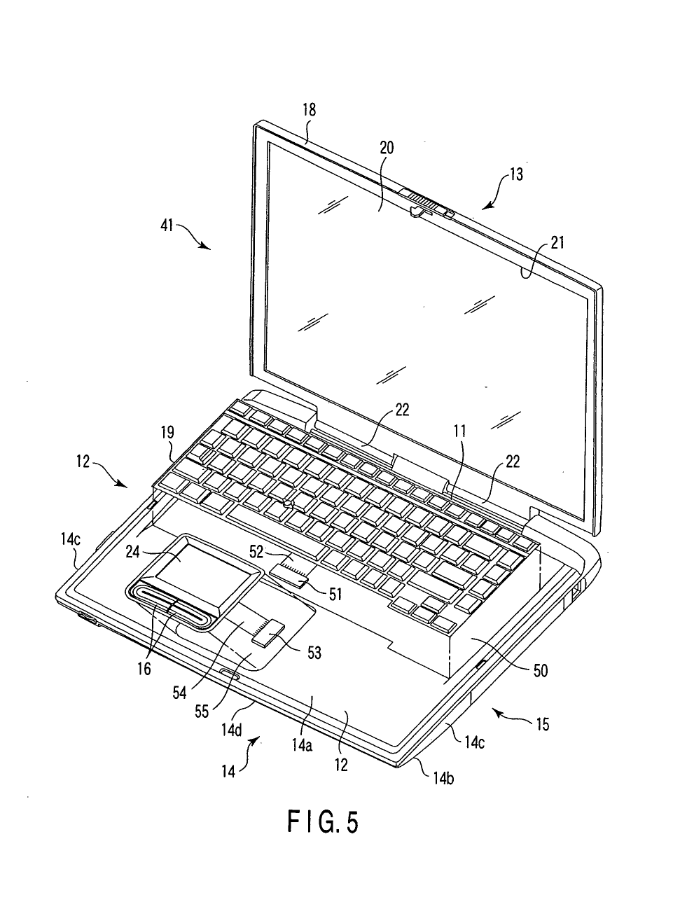

FIG. 5 is a schematic diagram illustrating an Experimental embodiment of an electronic apparatus according to the present invention.

A portable computer is explained herein as the electronic apparatus. As shown in FIG. 5, a portable computer 41 comprises an apparatus main body 12, and a display unit 13 supported by the apparatus main body 12. The apparatus main body 12 has a housing 14 formed of, for Experimental embodiment, synthetic resin. The housing 14 has a top cover 14a functioning as a first cover, and a base cover 15 functioning as a second cover, and has a flat and rectangular box shape. The base cover 15 has a bottom wall 14b opposing the top cover 14a, left and right side walls 14c standing from a peripheral portion of the bottom wall, a front wall 14d and a rear wall (not shown), which are formed as one unitary piece.

In the housing 14, a keyboard 19 is provided in a central portion of the top cover 14a. FIG. 5 illustrates a state where the keyboard 19 is dismounted. A connector 51 is mounted on a printed circuit board 50 included in a position below the keyboard 19, and one end of a flexible flat cable 52 is inserted into the connector 51. The other end of the flexible flat cable 52 is connected to a wiring board provided on a back surface of the keyboard 19.

A front end portion of an upper surface of the top cover 14a forms a palm rest portion 12. A touch pad 24 and a click button 16 are provided in almost the center of the palm rest portion 12. FIG. 5 illustrates a state where the touch pad 24 and the click button 16 are dismounted. Another printed circuit board 55 is provided below the touch pad 24 and the click button 16. The printed circuit board 55 is connected to the printed circuit board 50, and has a connector 53. One end of a flexible flat cable 54 is inserted into the connector 53. The other end of the flexible flat cable 54 is connected to a wiring board provided on the back surface of the touch pad 24 and the click button 16.

Further, speakers (not shown) are accommodated in the right and left of the front end portion in the housing 14.

The display unit 13 comprises a housing 18 having a flat and rectangular box shape, and a liquid crystal display panel 20 accommodated in the housing 18. The liquid crystal display panel 20 is exposed to the outside through a display window 21 formed in the housing 18. The housing 18 has a pair of leg portions 22 projecting from one end thereof. The leg portions 22 are rotatably supported by the rear end portion of the housing 14 by hinge portions (not shown). This structure enables the display unit 13 to rotate between a closed position where the display unit 13 is laid down to cover the keyboard 19 from above, and an open position where the display unit 13 stands in the rear of the keyboard 19.

The present invention is described in detail with reference to Experimental embodiments.

### Experimental Embodiment 1

Copper wires were subjected to tin plating, and thereby a tin plating layer was formed on the copper wires. Thereafter, the wires were subjected to rolling, and thereby copper wires having a thickness of 0.035 mm were obtained. The copper wires were introduced into an infrared heating device whose surface heating temperature was set to 220° C., heated therein for 1 minute, and then taken out of the infrared heating device and made stand to cool.

The copper wires were arranged, by a laminator, at regular intervals on an insulating belt-like sheet having a thickness of 0.0475 mm and formed of heat-resistant polyethylene terephthalate, and thereby an insulating belt-like sheet with conductors was obtained.

Thereafter, the tin-plated copper wires were subjected to surface analysis by a scanning electron microscope.

As a result, the copper wires were proved to have a tin-copper alloy phase existing on a copper phase and reaching the surface. However, a tin phase remained in some parts of the surface.

Table 1 below illustrates the obtained result of Experimental embodiment 1.

### Experimental Embodiments 2 to 5

Tin-plated copper wires were heated in the same manner as in Experimental embodiment 1, except that the respective surface heating temperatures were set to 240, 260, 280, and 300° C. Then, the compositions of the wires were checked in the same manner.

As a result, it was proved that a tin-copper alloy phase existed on a copper phase and reached to the surface, in the cases of using the surface heating temperatures of 240° C. and 260° C. However, a tin phase remained in some parts of the surface. Further, in the cases of using the surface heating temperatures of 280° C. and 300° C., a sufficient amount of tin-copper alloy phase existed on the copper phase, and little tin phase existed.

Table 1 below illustrates the obtained results of Experimental embodiments 2 to 5.

### Comparative Experimental Embodiments 1 and 2

Tin-plated copper wires were heated in the same manner as in Experimental embodiment 1, except that the respective surface heating temperatures were set to 200 and 320° C. Then, the compositions of the wires were checked in the same manner.

As a result, in the case of using the surface heating temperature of 200° C., only a tin phase existed on a copper phase, and no tin-copper alloy phase existed.

On the other hand, in the case of using the surface heating temperature of 320° C., a sufficient amount of tin-copper alloy phase existed on a copper phase, and little tin phase existed. However, cracks occurred on the surface.

Table 1 below illustrates the obtained results of Comparative Experimental embodiments 1 and 2.

TABLE 1

| | Heating Temperature | Judgment | Evaluation |
|---|---|---|---|
| Comparative | 200° C. | X | Sn did not melt. |
| Example 1 | | | |
| Example 1 | 220° C. | X | Sn—Cu alloy phase did not sufficiently |
| | | | grow, and pure Sn remained. |
| Example 2 | 240° C. | Δ | Sn—Cu alloy phase did not sufficiently |
| | | | grow, and pure Sn remained. |
| Example 3 | 260° C. | Δ | Sn—Cu alloy phase did not sufficiently |
| | | | grow, and pure Sn remained. |
| Example 4 | 280° C. | ⊚ | Sn—Cu alloy phase grew to a portion |
| | | | close to a surface layer, and little |
| | | | pure Sn remained. |
| Example 5 | 300° C. | X | Sn—Cu alloy phase grew to a portion |
| | | | close to a surface layer, and little |
| | | | pure Sn remained. |
| Comparative | 320° C. | X | Sn—Cu alloy layer grew to portion close |
| Example 2 | | | to a surface layer, but cracks occurred |
| | | | in a plated portion. |

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A flexible flat cable comprising:
a pair of insulating sheets having flexibility; and
a plurality of conductors which are arranged in lines at intervals between the insulating sheets, have at an end portion thereof a connecting portion exposed from the insulating sheet, and contain tin and copper as main components,
wherein the connecting portion has a first region containing copper as main component, and a second region which is provided on the first region and contains tin and copper as main components and at least part of a surface region of the second region is formed of a tin-copper alloy.

2. A flexible flat cable according to claim 1, wherein the connecting portion is obtained by annealing a copper wire and a tin layer plated on the copper wire at 220 to 300° C.

3. A printed circuit board comprising:
a substrate;
a conductor pattern provided on the substrate;
a connector which has a contact portion provided on the substrate in electrical connection with the conductor pattern and having a tin alloy coating layer, and a housing holding the contact portion and having a fitting port into which a connecting portion of a connecting part is fitted; and
a flexible flat cable as the connecting part, including: a pair of insulating sheets having flexibility; and a plurality of conductors which are arranged in lines at intervals between the insulating sheets, have at an end portion thereof a connecting portion exposed from the insulating sheet, and contain tin and copper as main component, the connecting portion having a first region containing copper as main component, and a second region which is provided on the first region and contains tin and copper as main components and at least part of a surface region of the second region is formed of a tin-copper alloy.

4. A printed circuit board according to claim 3, wherein the connecting portion is obtained by annealing a copper wire and a tin layer plated on the copper wire at 220 to 300° C.

5. An electronic apparatus comprising:
a printed circuit board including: a substrate; a conductor pattern provided on the substrate; a connector which has a contact portion provided on the substrate in electrical connection with the conductor pattern and having a tin alloy coating layer, and a housing holding the contact portion and having a fitting port into which a connecting portion of a connecting part is fitted, a flexible flat cable as the connecting part, including: a pair of insulating sheets having flexibility; and a plurality of conductors which are arranged in lines at intervals between the insulating sheets, have at an end portion thereof a connecting portion exposed from the insulating sheet, and contain tin and copper as main component, and
an electronic part connected to the printed circuit board by the flexible flat cable,
wherein the connecting portion has a first region containing copper as main component, and a second region which is provided on the first region and contains tin and copper as main components and at least part of a surface region of the second region is formed of a tin-copper alloy.

6. An electronic apparatus according to claim 5, wherein the connecting portion is obtained by annealing a copper wire and a tin layer plated on the copper wire at 220 to 300° C.
